(19) United States
(12) Patent Application Publication
(10) Pub. No.: US 2007/0145594 A1
(43) Pub. Date: Jun. 28, 2007

(54) Semiconductor device and method for manufacturing the same

(75) Inventor: Keun Soo Park, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/641,039

(22) Filed: Dec. 19, 2006

(30) Foreign Application Priority Data
Dec. 28, 2005 (KR) 10-2005-0132010
Dec. 28, 2005 (KR) 10-2005-0132482

(51) Int. Cl. H01L 23/48

(52) U.S. Cl. 257/763

(57) ABSTRACT

A semiconductor device includes a first metal layer formed on a semiconductor substrate and an interlayer insulating layer formed on the first metal layer, wherein a via hole is formed in the interlayer insulating layer. The semiconductor device further includes a second metal filled into the via hole at a predetermined height, a third metal layer pattern formed on the second metal, a silicon layer pattern formed on the third metal layer pattern, a first barrier metal formed on an inner wall of the via hole and on a top side of the silicon layer pattern, a fourth metal filled on the first barrier metal in the via hole, and a fifth metal layer formed on the interlayer insulating layer.

### FIELD OF THE INVENTION

The present invention relates to a semiconductor device and a method for manufacturing the same. More particularly, the present invention relates to a semiconductor device and a method for manufacturing a metal wiring of a semiconductor device.

### BACKGROUND OF THE INVENTION

Generally, a metal wiring is required to apply an electric signal to a semiconductor device, and a metal wiring process having a multi-layer metal structure of at least two metals is currently used for manufacturing a highly integrated semiconductor device. Such a conventional metal wiring process is described in detail with reference to FIGS. 1A to 1G.

Referring to FIGS. 1A to 1G, cross-section views are illustrated showing a method for manufacturing a semiconductor device according to a prior art. First, as shown in FIG. 1A, a first metal layer 2 is formed on a semiconductor substrate to apply an electric signal to a semiconductor device (not shown) formed on the semiconductor substrate. An interlayer insulating layer 4 is formed on the semiconductor substrate having thereon the first metal layer 2, and the interlayer insulating layer 4 is planarized by applying a chemical mechanical polishing (CMP) process to the interlayer insulating layer 4.

In the next step, as shown in FIG. 1B, a photoresist layer is coated on a top of the planarized interlayer insulating layer 4, and a first photoresist layer pattern 6 is then formed by using a mask. In addition, as shown in FIG. 1C, a via hole 8 is formed by etching the interlayer insulating layer 4, using the first photoresist layer pattern 6 as a mask. The first photoresist layer pattern 6 is then removed.

Next, as shown in FIG. 1D, a barrier metal 10 is deposited on the interlayer insulating layer 4a using a sputtering process and the first metal layer 2, and a second metal layer 12, is coated on a top of the deposited barrier metal 10.

As shown in FIG. 1E, a barrier metal 10a and a second metal 12a are only formed inside of the via hole 8 by performing a chemical mechanical polishing (CMP) or an etch-back process to the barrier metal 10 and the second metal layer 12.

Thereafter, as shown in FIG. 1F, a third metal layer 14 is formed on the interlayer insulating layer 4a and the second metal 12a by a sputtering process. In succession, a photoresist layer is coated on a top of the third metal layer 14, and a second photoresist layer pattern 16 is then formed by patterning the photoresist layer.

As shown in FIG. 1G, a third metal layer pattern 14a is formed on a via hole 8 by dry etching the third metal layer 14 through the use of the second photoresist layer pattern 16 as a mask. Subsequently, the first metal layer 2 and the third metal layer pattern 14a are electrically connected by the barrier metal 10a and the second metal 12a in the via hole 8.

A metal wiring of a conventional semiconductor device described above is formed by a previously defined design. Accordingly, more installations of fabrications are required for foundry companies to respectively manufacture devices desired by a customer.

Furthermore, because a metal layer is formed in a multi-layer structure in order to form a metal wiring of the semiconductor device useful at a high voltage, the probability of error generation may increase as the number of metal layers increases.

### SUMMARY OF THE INVENTION

Therefore, it is an object of the present invention to provide a semiconductor device capable of flowing current by forming an insulating layer at an inner space of a via hole when a voltage is applied to a portion desired by a customer with a program and a method for manufacturing the same.

In accordance with a preferred embodiment of the present invention, there is provided a semiconductor device including:

a first metal layer formed on a semiconductor substrate;

an interlayer insulating layer formed on the first metal layer, wherein a via hole is formed in the interlayer insulating layer;

a second metal filled into the via hole at a predetermined height;

a third metal layer pattern formed on the second metal;

a silicon layer pattern formed on the third metal layer pattern;

a first barrier metal formed on an inner wall of the via hole and on a top side of the silicon layer pattern;

a fourth metal filled on the first barrier metal in the via hole; and

a fifth metal layer formed on the interlayer insulating layer.

In accordance with another preferred embodiment of the present invention, there is provided a method for manufacturing a semiconductor device, the method including the steps of: selectively etching a first interlayer insulating layer formed on a first metal layer, thereby forming a first via hole;

filing a second metal into the first via hole;

sequentially forming a third metal layer and a silicon layer on the first interlayer insulating layer including the first via hole and selectively etching the third metal layer and the silicon layer, thereby forming a third metal layer pattern and a silicon layer pattern;

forming a second interlayer insulating layer on the silicon layer pattern and the first interlayer insulating layer and selectively etching the second interlayer insulating layer, thereby forming a second via hole;

sequentially forming a first barrier metal layer and a fourth metal layer on the second interlayer insulating layer including the second via hole;

selectively etching the first barrier metal layer and the fourth metal layer, thereby filing a first barrier metal and a fourth metal into the second via hole; and

forming a fifth metal layer on the second interlayer insulating layer and patterning the fifth metal layer, thereby forming a fifth metal layer pattern.

### BRIEF DESCRIPTION OF THE DRAWINGS

The above and other objects and features of the present invention will become apparent from the following description of preferred embodiments given in conjunction with the accompanying drawings, in which:

FIGS. 1A to 1G are cross-section views showing a method for manufacturing a prior art semiconductor device;

FIGS. 2A to 2M are cross-section views illustrating a method for manufacturing a semiconductor device in accordance with one embodiment of the present invention; and

FIGS. 3A to 3K are cross-section views illustrating a method for manufacturing a semiconductor device in accordance with another embodiment of the present invention.

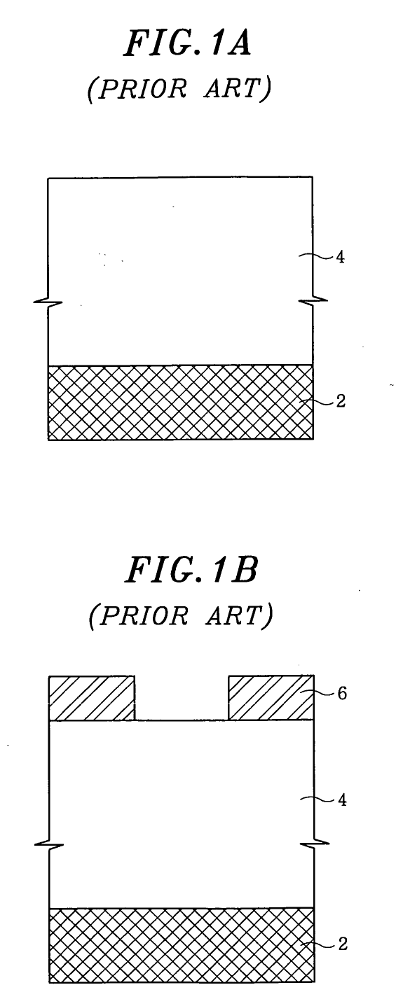

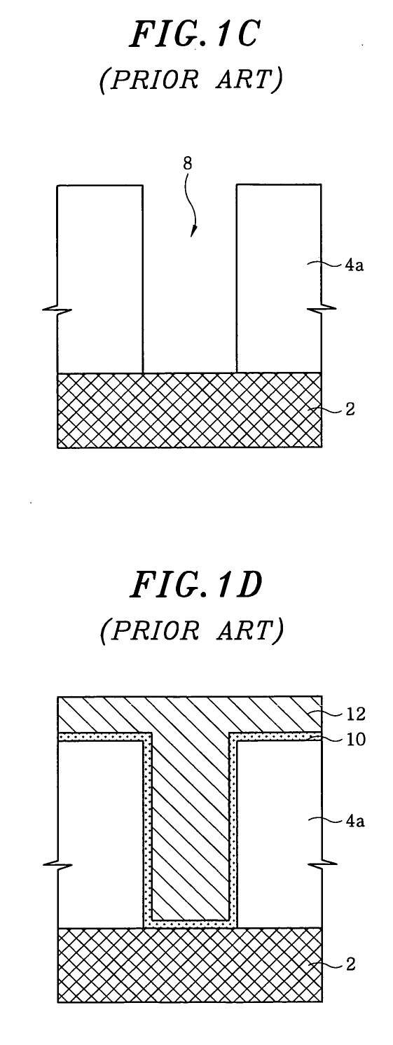

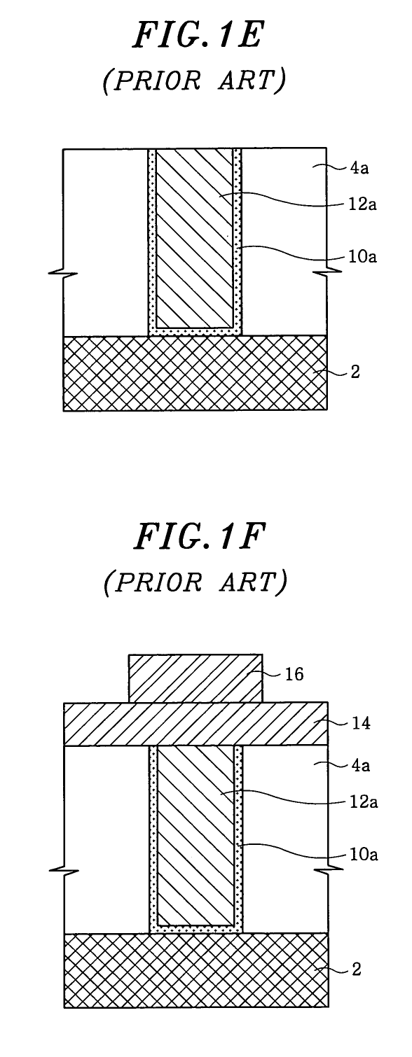

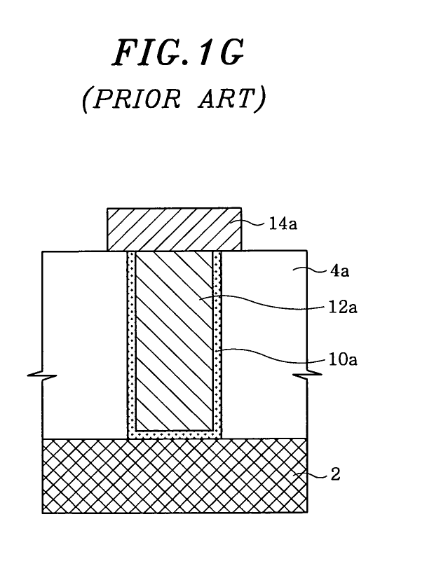

### DETAILED DESCRIPTION OF THE PREFERRED EMBODIMENTS

Hereinafter, preferred embodiments of the present invention will be described in detail with reference to the accompanying drawings so that they can be readily implemented by those skilled in the art.

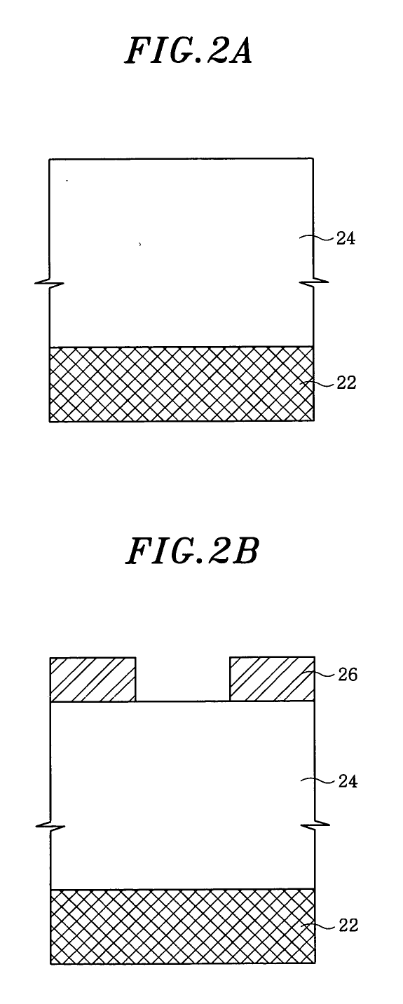

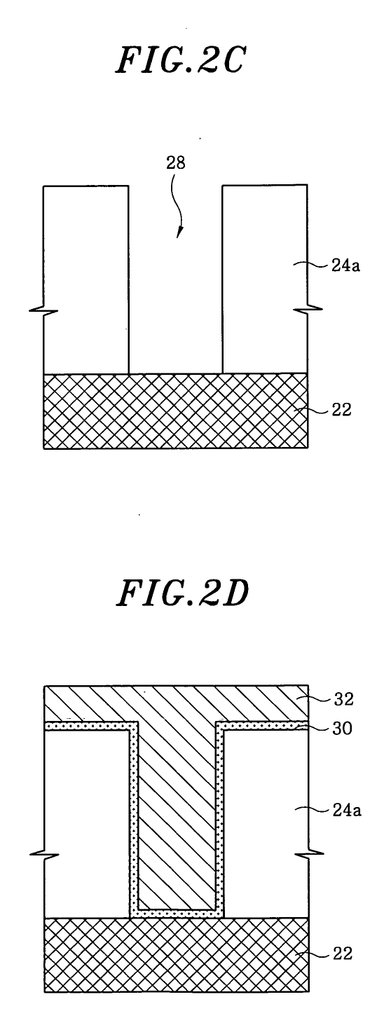

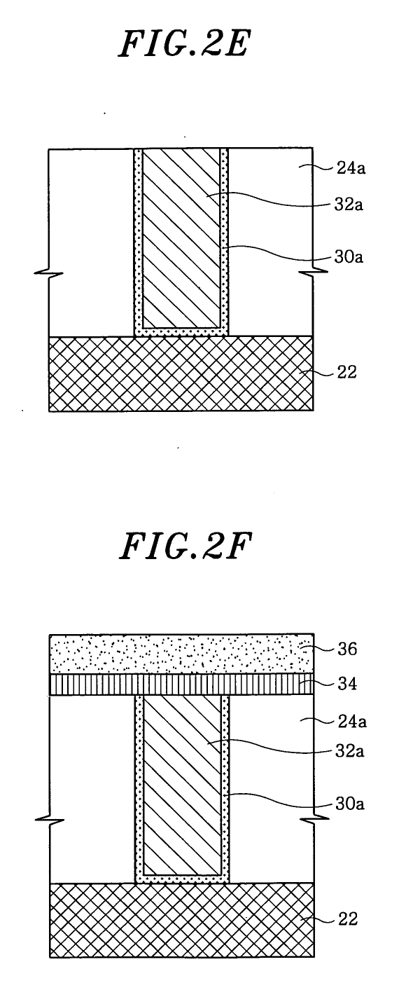

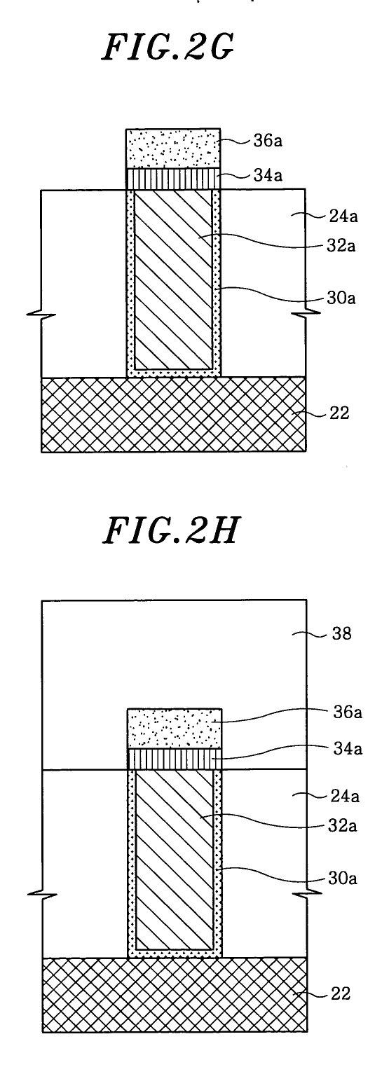

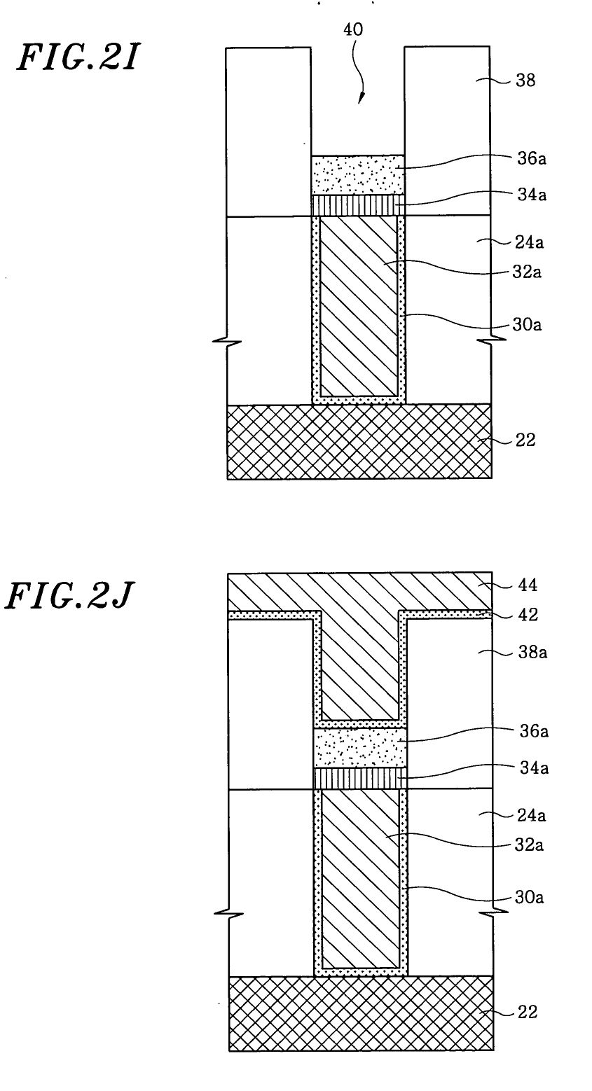

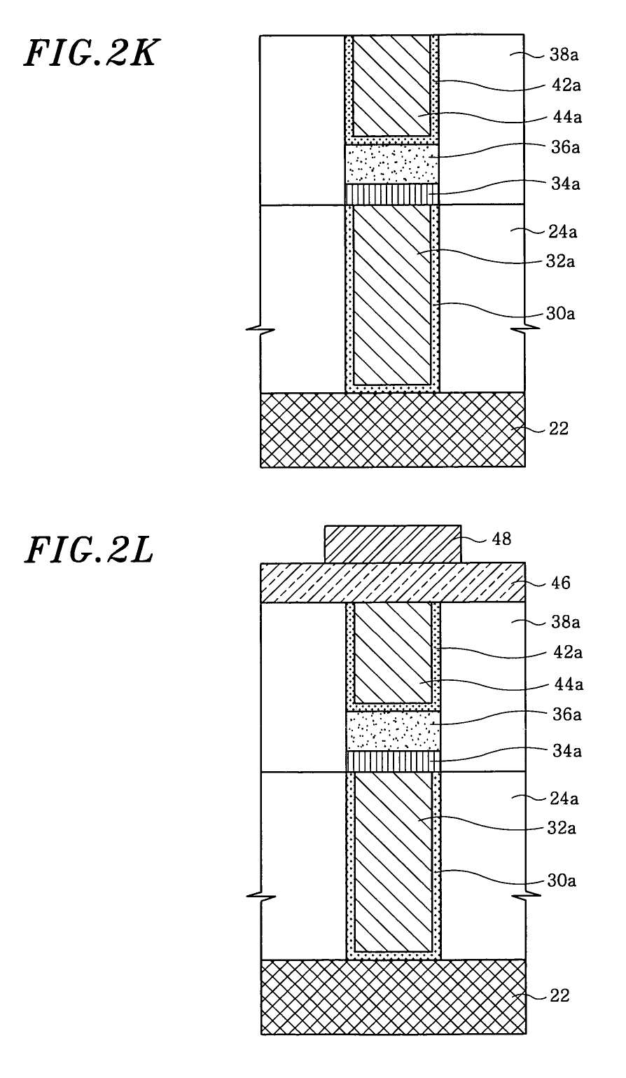

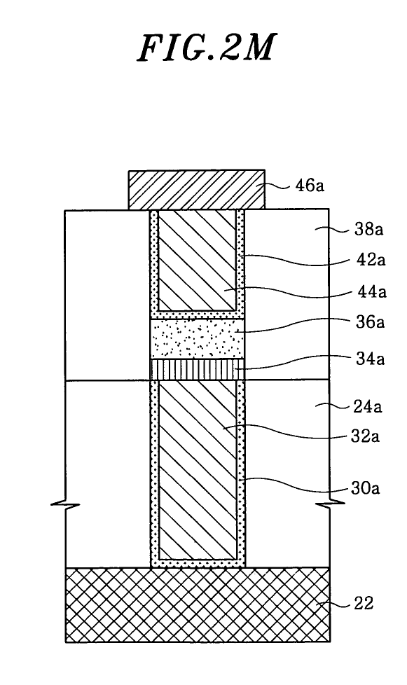

FIGS. 2A to 2M are illustrated cross-section views illustrating a method for manufacturing a semiconductor device in accordance with one embodiment of the present invention.

First, as shown in FIG. 2A, a first metal layer 22 is formed on a semiconductor substrate (not shown) to apply an electric signal to a semiconductor device. A first interlayer insulating layer 24 is then formed on the first metal layer 22, and the first interlayer insulating layer 24 is planarized by applying a chemical mechanical polishing (CMP) process to the formed interlayer insulating layer 24.

As shown in FIG. 2B, a photoresist layer is coated on a top of the planarized first interlayer insulating layer 24, and a first photoresist layer pattern 26 is formed by using a mask. Next, as shown in FIG. 2C, a first via hole 28 is formed by using the first photoresist pattern 26 as a mask, and the first photoresist layer pattern 26 is then removed.

Thereafter, as shown in FIG. 2D, a first barrier metal layer 30 is deposited by a sputtering process, and a second metal layer 32 is coated on the deposited first barrier metal layer 30. In the preferred embodiment of the present invention, it is preferable that a first barrier metal layer 30 is made of titanium and a second metal layer 32 is made of tungsten.

As shown in FIG. 2E, a first barrier metal 30a and a second barrier metal 32a are filled into the first via hole by planarizing the first barrier metal layer 30 and the second metal layer 32 with a CMP or an etch-back process.

As shown in FIG. 2F, a third metal layer 34 and a silicon layer 36 are formed on the first interlayer insulating layer 24a, including the first via hole 28a in which the first barrier metal 30a and the second metal 32a are filled. In the preferred embodiment of the present invention, it is preferable that the third metal layer 34 is made of titanium and the silicon layer 36 is made of amorphous silicon.

As shown in FIG. 2G, a third metal layer pattern 34a and a silicon layer pattern 36a are formed by selectively etching the third metal layer 34 and the silicon layer 36, respectively. In the preferred embodiment of the present invention, it is preferable that widths of the third metal layer pattern 34a and the silicon layer pattern 36a are substantially equal to that of the first via hole 28a.

Thereafter, as shown in FIG. 2H, a second interlayer insulating layer 38 is formed on the silicon layer pattern 36a and the first interlayer insulating layer 24a. In addition, as shown in FIG. 2I, a second via hole 40 is formed by selectively etching the second interlayer insulating layer 38 to expose the silicon layer pattern 36a. In the preferred embodiment of the present invention, it is preferable that the second via hole 40 and the silicon layer pattern 36a are approximately equal to each other in width.

As shown in FIG. 2J, a second barrier metal layer 42 and a fourth metal layer 44 are sequentially deposited on the second interlayer insulating layer 38a, including the second via hole 40, by a sputtering process. In some embodiments, the second barrier metal layer 42 is made of titanium and the fourth metal layer 44 is made of tungsten.

As shown in FIG. 2K, the second barrier metal 42a and the fourth metal 44a are filled into the second via hole 40 by planarizing the second barrier metal layer 42 and the fourth metal layer 44 through a CMP or an etch-back process.

As shown in FIG. 2L, a fifth metal layer 46 is formed by a sputtering process, and a second photoresist pattern 48 is formed by coating and patterning a photoresist layer on a top of the fifth metal layer 46.

As shown in FIG. 2M, a fifth metal layer pattern 46a is formed on a top of the second via hole 40a by dry etching the fifth metal layer 46 through the use of the second photoresist pattern 48 as a mask. A metal wiring of the semiconductor device is then formed by removing the second photoresist layer pattern 48.

Thereafter, if a desired voltage is applied to the semiconductor device manufactured by the above-described method, the first metal layer 22 and the fifth metal layer pattern 46a are electrically connected since silicide is formed between the second barrier metal 42a and a top side of the silicon layer pattern 34 and between the third metal layer pattern 34a and the silicon layer pattern 36a.

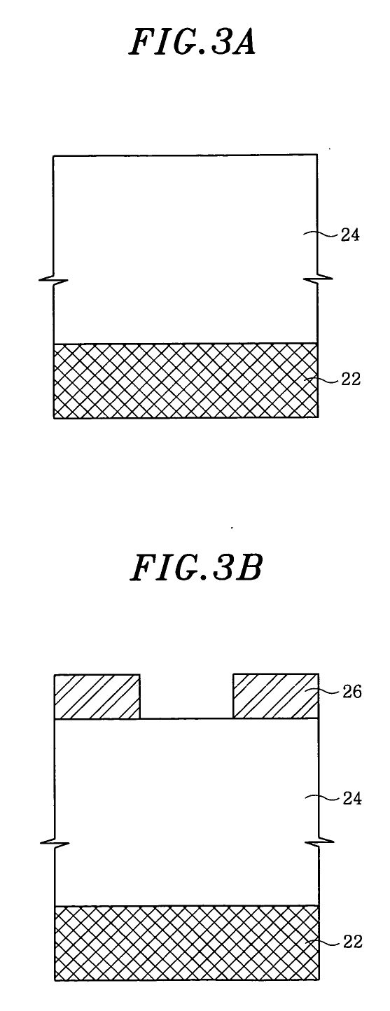

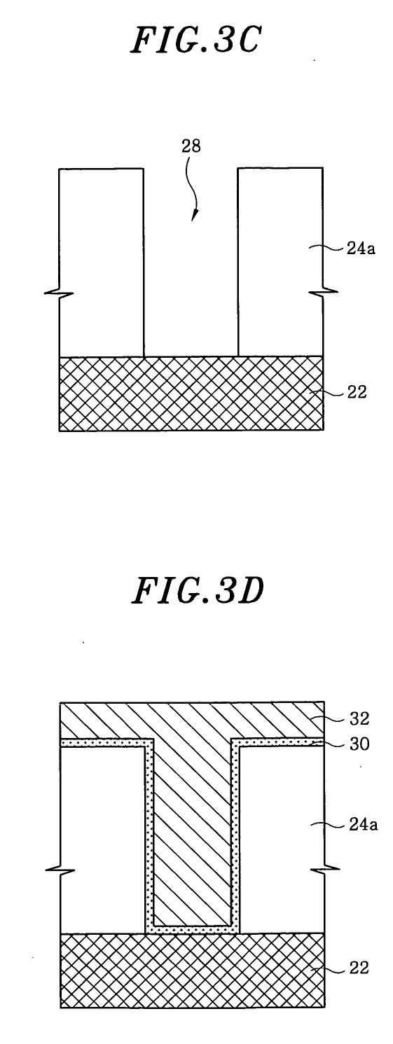

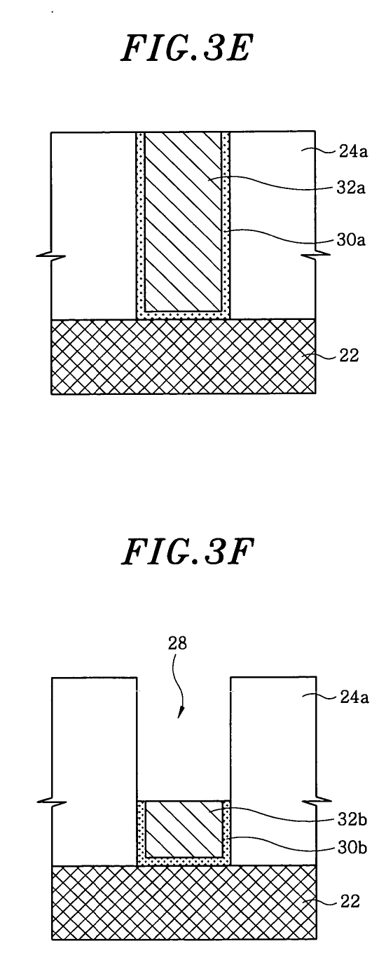

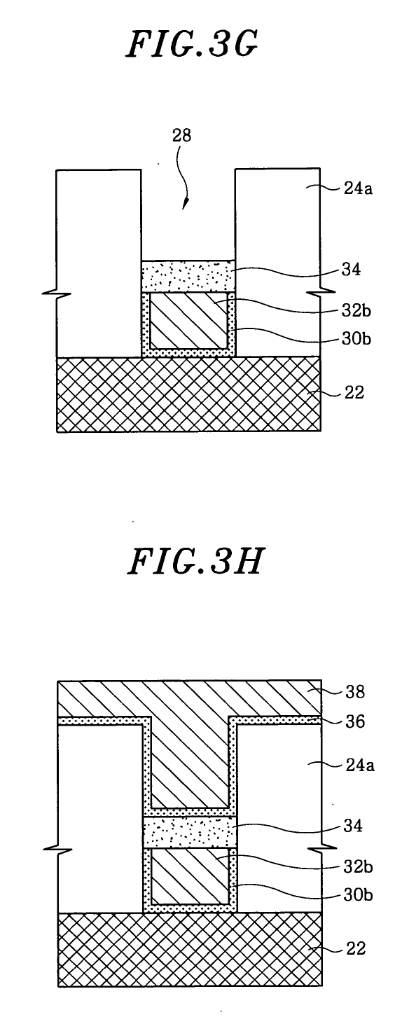

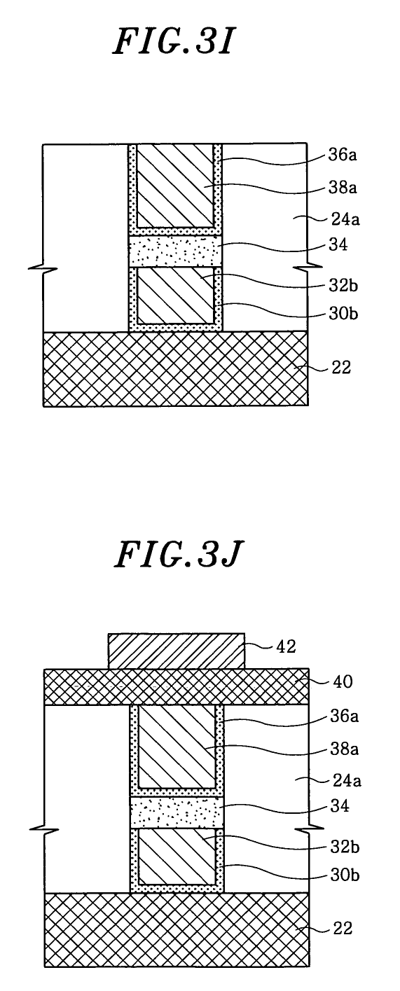

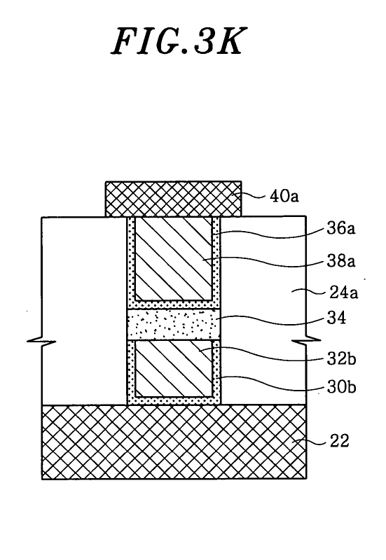

Referring to FIGS. 3A to 3K, cross-section views illustrate a method for manufacturing a semiconductor device in accordance with another embodiment of the present invention.

Referring to FIGS. 3A to 3E, the method of manufacturing the semiconductor device in accordance with another embodiment of the present invention is substantially similar to that disclosed in reference to FIGS. 2A to 2E. Therefore, descriptions for the same processes with one embodiment of the present invention will be omitted.

Now, referring to FIG. 3F, a first barrier metal 30a and a second metal 32a are etched to a predetermined height by performing an etch-back process to the first barrier metal 30a and the second metal 32a, thereby obtaining a first barrier metal pattern 30b and a second metal pattern 32b. And, as shown in FIG. 3G, a silicon layer 34 is formed on the first barrier metal pattern 30b and the second metal pattern 32b in a via hole 28. In the preferred embodiment of the present invention, it is preferable that the silicon layer 34 is made of amorphous silicon and a height of the silicon layer 34 is lower than that of the interlayer insulating layer 24a.

Thereafter, as shown in FIG. 3H, a second barrier metal layer 36 and a third metal layer 38 are sequentially deposited on the silicon layer 34 and the interlayer insulating layer 24a by a sputtering process. In the preferred embodiment of the present invention, it is preferable that the second barrier metal layer 36 is made of titanium and the third metal layer 38 is made of tungsten.

As shown in FIG. 3I, a second barrier metal 36a and a third metal 38a are filled into the via hole 28 by planarizing the second barrier metal layer 36 and the third metal layer 38 through a CMP process.

As shown in FIG. 3J, a fourth metal layer 40 is formed by a sputtering process and a second photoresist layer pattern 42 is formed by coating and patterning a photoresist layer on a top of the fourth metal layer 40.

As shown in FIG. 3K, a fourth metal layer pattern 40a is formed on a top of the via hole 28 by dry etching the fourth metal layer 40 through the use of the second photoresist layer pattern 42 as a mask, and a metal wiring of the semiconductor device is then formed by removing the second photoresist layer pattern 42.

Thereafter, if a desired voltage is applied to the semiconductor device manufactured by the above-described method, the first metal layer 22 and the fourth metal layer pattern 40a are electrically connected because silicide is formed between the first barrier metal 32b and the silicon layer 34 and between the second barrier metal 36a and the silicon layer 34 through the generation of heat.

It should be understood that those skilled in the art implement the present invention in various other shapes without departing from the technical spirit or necessary characteristics of the invention. For example, in accordance with the above-described embodiment of the present invention, although it is described that the silicon layer is formed on the first barrier metal and the second metal, a barrier metal layer made of titanium can be additionally formed on the first barrier metal and the second metal in order to more easily form the silicide between the silicon layer and the barrier metal.

According to the present invention, as described above, by forming an insulating layer inside of a via hole with amorphous silicon, a current flows when a desired voltage is applied to a portion desired by a client with a program, a semiconductor device can be implemented according to an operational voltage desired by the client or the semiconductor device desired by the client can be supplied without installing more fabrications.

While the invention has been shown and described with respect to the preferred embodiments, it will be understood by those skilled in the art that various changes and modifications may be made without departing from the spirit and scope of the invention as defined in the following claims.

What is claimed is:

1. A semiconductor device comprising:
a first metal layer formed on a semiconductor substrate;
an interlayer insulating layer formed on the first metal layer, wherein a via hole is formed in the interlayer insulating layer;
a second metal filled into the via hole at a predetermined height;
a third metal layer pattern formed on the second metal;
a silicon layer pattern formed on the third metal layer pattern;
a first barrier metal formed on an inner wall of the via hole and on a top side of the silicon layer pattern;
a fourth metal filled on the first barrier metal in the via hole; and
a fifth metal layer formed on the interlayer insulating layer.

2. The semiconductor device of claim 1, further comprising:
a second barrier metal formed between the inner wall of the via hole and the second metal and between the first metal layer and the second metal.

3. The semiconductor device of claim 1, wherein the first barrier metal and the fourth metal are planarized to the same height with the interlayer insulating layer through a chemical mechanical polishing(CMP) process.

4. The semiconductor device of claim 1, wherein the fifth metal layer pattern is formed to cover the via hole.

5. The semiconductor device of claim 1, wherein the third metal layer pattern, the first barrier metal and the second barrier metal are made of titanium.

6. The semiconductor device of claim 1, wherein silicide is formed between the third metal layer pattern and the silicon layer and between a top side of the silicon layer and the first barrier metal when a voltage is applied to the semiconductor device.

7. A method for manufacturing a semiconductor device, the method comprising the steps of:
forming a first via hole by selectively etching a first interlayer insulating layer formed on a first metal layer;
filing a second metal into the first via hole;
sequentially forming a third metal layer and a silicon layer on the first interlayer insulating layer including the first via hole, and selectively etching the third metal layer and the silicon layer, thereby forming a third metal layer pattern and a silicon layer pattern;
forming a second interlayer insulating layer on the silicon layer pattern and the first interlayer insulating layer, and selectively etching the second interlayer insulating layer, thereby forming a second via hole;
sequentially forming a first barrier metal layer and a fourth metal layer on the second interlayer insulating layer including the second via hole;
selectively etching the first barrier metal layer and the fourth metal layer, thereby filing a first barrier metal and a fourth metal into the second via hole; and
forming a fifth metal layer on the second interlayer insulating layer and patterning the fifth metal layer, thereby forming a fifth metal layer pattern.

8. The method of claim 7, further comprising the step of:
forming a second barrier metal on a sidewall of an inside of the first via hole and on a top side of the first metal layer before the second metal filling step.

9. The method of claim 7, wherein the step of filling the first barrier metal and the fourth metal, further includes the step of planarizing the first barrier metal layer and the fourth metal layer to a same height with the second interlayer insulating layer through a chemical mechanical polishing (CMP) process applied to the first barrier metal layer and the fourth metal layer, thereby filling the first barrier metal and the fourth metal into the second via hole.

10. The method of claim 7, wherein the fifth metal layer pattern is formed to cover the second via hole.

11. The method of claim 7, wherein the second via hole is formed by a width equal to that of the first via hole.

12. The method of claim 7, wherein the third metal layer pattern, the first barrier metal and the second barrier metal are made of titanium.

13. The method of claim 7, further comprising the step of:
forming silicide between the third metal layer pattern and the silicon layer and between a top side of the silicon layer and the first barrier metal by applying a voltage to the semiconductor device.

14. A semiconductor device, comprising:
a first metal layer formed on a semiconductor substrate;
an interlayer insulating layer formed on the first metal layer, wherein a via hole is formed in the interlayer insulating layer;
a second metal filled into the via hole to a predetermined height;
a first barrier metal layer formed between an inner wall of the via hole and the second metal and between the first metal layer and the second metal;
a silicon layer formed on the first barrier metal and the second metal to a predetermined height;
a third metal filled on the top side of the silicon layer inside of the via hole;
a second barrier metal formed between the inner wall of the via hole and the third metal and between the silicon layer and the third metal; and
a fourth metal layer pattern formed on the interlayer insulating layer.

15. The semiconductor device of claim 14, wherein a height of the silicon layer is lower than that of the interlayer insulating layer.

16. The semiconductor device of claim 14, wherein the second barrier metal and the third metal are planarized to the same height with the interlayer insulating layer through a chemical mechanical polishing (CMP) process.

17. The semiconductor device of claim 14, wherein the fourth metal layer pattern is formed to cover the via hole.

18. The semiconductor device of claim 14, wherein the first barrier metal and the second barrier metal are made of titanium.

19. The semiconductor device of claim 14, wherein silicide is formed between the first barrier metal and the silicon layer and between the silicon layer and the second barrier metal when a voltage is applied to the semiconductor device.

20. A method for manufacturing a semiconductor device, the method comprising the steps of:
selectively etching an interlayer insulating layer formed on a first metal layer, thereby forming a via hole;
sequentially forming a first barrier metal layer and a second metal layer on the interlayer insulating layer including the via hole;
planarizing the second metal layer and the first barrier metal layer and filling a first barrier metal and a second metal into the via hole;
etching the second metal and the first barrier metal in the via hole to a predetermined height;
forming a silicon layer on the first barrier metal and the second metal to a predetermined height;
sequentially forming a second barrier metal layer and a third metal layer on the interlayer insulating layer including the via hole;
planarizing the first barrier metal layer and the second metal layer and filling a second barrier metal and a third metal on a top side of the silicon layer in the via hole; and
forming a fourth metal layer on the interlayer insulating layer and patterning the fourth metal layer, thereby forming a fourth metal layer pattern.

21. The method of claim 20, wherein a height of the silicon layer is lower than a height of the interlayer insulating layer.

22. The method of claim 20, wherein the second barrier metal and the third metal are planarized to the same height with the interlayer insulating layer by using a chemical mechanical polishing (CMP) process or an etch-back process.

23. The method of claim 20, wherein the fourth metal layer pattern is formed to cover the via hole.

24. The method of claim 20, wherein the first barrier metal and the second barrier metal are made of titanium.

25. The method of claim 20, wherein silicide is formed between the first barrier metal and the silicon layer and between the silicon layer and the second barrier metal when a voltage is applied to the semiconductor device.
